(19) United States
(12) Patent Application Publication
(10) Pub. No.: US 2014/0147590 A1
(43) Pub. Date: May 29, 2014

(54) METHOD FOR PRODUCING A COATING ON AN EXTRUSION DIE

(71) Applicant: WEFA Singen GmbH, Singen (DE)

(72) Inventors: Joachim Maier, Singen (DE); Oliver Maier, Radolfzell (DE); Werner Buergin, Sissach (CH); Helga Holzschuh, Mehrstetten (DE)

(73) Assignee: WEFA Singen GmbH, Singen (DE)

(21) Appl. No.: 14/128,680

(22) PCT Filed: Dec. 29, 2011
(86) PCT No.: PCT/EP2011/074224

§ 371 Date: Jan. 21, 2014

(30) Foreign Application Priority Data
Jun. 22, 2011 (DE) 10 2011 051 276.4

(51) Int. Cl. C23C 16/06

(52) U.S. Cl. CPC C23C 16/06
USPC 427/250

(57) ABSTRACT

A method for producing a coating of one or more layers on an extrusion die as a substrate body of a heat-resistant and/or long-term heat-resistant steel material by means of chemical vapour deposition (CVD), comprising the steps of: providing the substrate body from hot-work tool steel, which is intended for interacting with ductile extrusion metal, introducing a first reaction gas, comprising a metal, in particular titanium, into a reactor receiving the substrate body, to provide a coating metal, introducing a second reaction gas, comprising a carbon compound, into the reactor, to provide carbon for the coating, wherein the first and/or the second reaction gas or a further reaction gas provide(s) nitrogen for the coating, and carrying out a CVD coating process with the reaction gases.

### BACKGROUND OF THE INVENTION

The present invention pertains to the field of extrusion technology, particularly a method for producing a coating on an extrusion die. Suitable extrusion metal, typically an aluminum alloy, is pressed through an opening that is at least sectionally defined by an extrusion die under high pressure and has a ductile, viscous consistency during this pressing operation and while passing through the die such that it can be shaped into a suitable or even complex profile configuration depending on the design of the extrusion die.

The design of the die and the material (substrate) used for the die are subject to special requirements, among other things, due to the special circumstances of the extrusion technology, namely a continuous and comparatively slow flow of the ductile extrusion metal along the (stationary) die surface under high pressure and at a high temperature. On the one hand, a particularly wear-resistant surface needs to be ensured, particularly in the contact regions with the extrusion metal, wherein this is typically realized with a respective coating or surface treatment (nitriding, etc.) that increases the surface hardness. On the other hand, the special conditions of the extrusion process, as well as the special geometries (long projections, thin webs) of the extruded profiles, require a certain ductility of the die and therefore prohibit the otherwise conceivable utilization of particularly hard (but brittle) materials such as, e.g., hard metals or high-speed steels. Due to the high operating temperatures between the 500° C.-640° C., the steels used are furthermore subject to stricter requirements with respect to the retention of hardness and the long-term heat resistance, wherein this precludes the potential utilization of cold-work tool steels as material for such an extrusion die.

According to the pertinent prior art, it is basically known to apply a coating that increases the wear resistance by means of so-called high-temperature (HT) CVD processes in order to produce coated dies for the extrusion technology. For example, EP 1 011 885 B1 of the applicant discloses a method for coating an extrusion die by means of high-temperature CVD, in which a metallic phase is applied (in otherwise conventional fashion) onto the substrate surface, namely the suitably prepared and shaped die, by means of the CVD process. Preferred operating temperatures during this high-temperature process lie above 950° C.; at these temperatures, the gases used have an optimal reactivity for vapor deposition. At lower temperatures, in contrast, the gases cannot be deposited with adequate process stability and with sound layer properties by means of HT-CVD.

This high temperature used in the prior art, in particular, also causes the hot-work tool steels to significantly overheat and overtime at the high CVD temperatures. This leads to embrittlement, grain growth, grain boundary precipitates and an associated, significantly reduced toughness (of typically 400 J down to 150-300 J in compliance with the impact bending test according to DIN SEP 1314). Consequently, the extrusion dies still wear out relatively fast such that there is a demand for optimization in this respect.

Although the aforementioned publication also formally discloses a temperature range that is downwardly expanded to 700° C. and therefore shifted from the high-temperature range into the so-called medium temperature range, the described method representing the most closely related prior art does not make it possible to achieve a sufficiently tough and hard layer in connection with a substrate microstructure that promotes the ductile values and therefore the wear resistance. Such a low temperature would without further measures prevent, in particular, a sufficient deposition of carbon as an element and component of the hardening layer such that, according to the invention, the wear and hardness properties of a CVD coating that is hypothetically deposited at temperatures below 1000° C. would be insufficient and a person skilled in the pertinent prior art would not consider such a variation in practical coating processes and for extrusion dies anyway.

### SUMMARY OF THE INVENTION

The objective of the invention is attained with the method for producing a single-layer or multilayer coating on a substrate body in the form of an extrusion die.

According to the invention, it was initially determined that especially the concentration of carbon, particularly the relative concentration of carbon to the element nitrogen, is critical for the improved hardness properties to be achieved. This hardness also leads, in particular, to an improved supporting effect when a potential additional cover layer is used in accordance with an enhancement of the invention.

Although the technology disclosed in the prior art does not make it possible to realize the required high carbon concentration (particularly at low temperatures in the so-called medium temperature range, namely below 1000° C.), it was furthermore determined, according to the invention, that a significant increase of this respective concentration or C/N ratio can be advantageously achieved with the inventive additional supply of suitable carbon-containing gas flows as (additional) reaction gas.

According to the invention, it was furthermore determined that the restriction of the process temperature in the inventive CVD coating process for producing a single-layer or multilayer coating has no negative effect on the surface properties of the die (as it is the case, e.g., in the known high-temperature process), i.e. no deterioration of the substrate microstructure occurs (as a result of high operating temperatures), wherein the surface has a substantially higher toughness and elasticity than typically brittle high-temperature CVD surfaces and, as initially discussed, therefore is particularly suitable for extrusion processes.

Another advantageous effect of the present invention can be seen in that carrying out the CVD coating process at the inventive medium temperature, especially in the range between 700° C. and 950° C., particularly in the range between 850° C. and 900° C., creates an advantageous columnar and/or stalky structure with a plurality of microstructure sections that are arranged adjacent and typically parallel to one another and have a growth direction (grain orientation) that is aligned perpendicular to the substrate surface. In this context, “columnar” and “stalky” respectively refer to a layer structure, in which the grain orientation develops parallel to the growth direction, namely similar to adjacent column structures that typically extend about perpendicular to the substrate surface and/or layer surface, and results in an arrangement of elongated structure sections that are respectively delimited from adjacent columns and potentially allow the deposition of elements into the intermediate spaces between adjacent columns; in this context, the term “column” does not necessarily refer to cylindrical arrangements, but rather to the primarily important attribute of a directed structure/texture (e.g. in the direction of the [100] structure) that can be clearly detected in such a layer, e.g., with common analytical methods or visualization methods.

The stalky structure in turn improves the wear properties, reduces the surface roughness and improves the diffusibility of the doping elements, as well as the thermal conductivity. These properties are advantageous for the utilization in extrusion processes. A suitable doping material (typically oxygen or boron, Cr, Zr) can then diffuse into the intermediate spaces of such a microstructure that counteracts the disadvantageous brittleness of the material and, according to the invention, result in particularly favorable surface properties that counteract a disadvantageous adherence/inherence or abrasion.

An advantageous consequence of this inventive measure is the option of lowering the processing temperature of the extrusion material in comparison with conventional processes during the pressing operation (or while the extrusion material passes through the extrusion die) because the reduced adherence results, as described above, in a reduced coefficient of friction of the die surface (due to reduced roughness and improved thermal conductivity). A lower process temperature during the extrusion process in turn prevents disadvantageous oxidation effects of the extrusion material and positively affects the quality of the extruded product.

Although the present invention is particularly suitable for realizing the inventive (single-layer or multilayer) coating in the form of a MT-TiCN (or MT-TiCNO or, in doped form, MT-TiCBNO) coating, in which “MT” describes the claimed medium temperature range between 700° C. and 950° C., preferably <900° C., and “TiCN” indicates the presence of the respective elements in the coating, the present invention likewise makes it possible to use alternative metals, e.g., instead of Ti or to add other metals, as well as to optionally influence the material in other ways with suitable doping elements as already mentioned above.

In a generalization of the invention, for example, the stoichiometry of the inventive MT-TiCN process with respect to other potential metals for the coating of extrusion dies would look as follows:

2 MeClₙ+CH₃CN+(n+0.5) H₂→2 MeC_{0.5}+N_{0.5}+CH₄+2n HCl

(Me=metal)

In the preferred utilization of Ti as metal in accordance with the present invention, the following reaction equation could apply if suitable precursor gases are used:

2TiCl₄+4H2+N2→2TiN+8HCl

The Ti-based layers are primarily used as a base layer that provides an improved supporting effect for one or more additional cover layer(s) with specific properties applied in accordance with enhancements of the invention, wherein the specific stalky structure of the base layer is partially transferred to the cover layer(s).

According to the invention, the favorable ratio of C/N>1, preferably C/N≧1.5 (measured, e.g., by means of secondary ion mass spectroscopy SiMs), can be advantageously achieved, in particular, by providing the second reaction gas that makes available the element carbon for the coating and by using the inventive medium temperature, wherein a typical realization of the invention allows, e.g., a C:N ratio of 60:40.

In the inventive medium-temperature CVD method, the second reaction gas in the form of a typical so-called precursor is typically supplied in the form of acetonitrile (CH₃CN), but it would also be conceivable to use other gases that provide carbon compounds for the coating.

According to preferred enhancements of the invention, it is also proposed to provide the coating applied during the course of the inventive medium-temperature CVD coating process with a cover layer that is optimized, for example, with respect to texture, roughness and thermal conductivity (and once again consists of at least a single layer). A typical cover layer could contain, e.g., Al2O3, TiBN or TiO, wherein it was determined that, according to preferred exemplary embodiments for applying the cover layer, it is by all means possible to apply the cover layer itself at CVD process temperatures above the medium-temperature range, i.e. above 950° C., without impairing the advantageous properties of the overall arrangement. A cover layer containing ZrN, CrN or CrC would basically also be conceivable.

These measures result in a die that is structured in the form of an inventive coating on a typical hot-work tool steel or similar substrate material and is suitable for realizing a plurality of extruded profiles, as well as for nearly arbitrary extrusion metals, namely also abrasive (and therefore particularly wear-promoting, e.g. due to their Si content) and adherent (Cu- or Mn-containing) extrusion metals. In accordance with preferred applications of the invention, it is therefore sensible to coat different exposed or wear-prone sections and regions of an extrusion die in the inventive fashion, wherein the present invention is also particularly advantageous with respect to especially wear-prone curvature sections, sliding sections, supporting sections or conical sections of an extrusion die.

According to the invention, typical coating thicknesses advantageously lie in the range between 5μ-15μ and usually make it possible to achieve a surface hardness in the range between 2000 and 3500 HV, particularly a hardness range between 2500 and 3000 HV.

### BRIEF DESCRIPTION OF THE DRAWINGS

Other advantages, characteristics and details of the invention result from the following description of preferred exemplary embodiments, as well as the drawings; in these drawings:

FIG. 1 shows a longitudinal section through an extrusion die provided with a coating in accordance with the present invention;

FIG. 2 shows a perspective view of the die according to FIG. 1 with an extruded profile (e.g. tubes)supplied on one end and a tubular profile formed by the die on the other end (outlet side);

FIG. 3 shows a schematic view of a layer produced on a surface of the extrusion die by means of a method for producing a single-layer coating according to a first embodiment of the present invention;

FIG. 4 shows a detailed view of the multilayer structure of a multilayer coating produced on a surface of the extrusion die in accordance with a second embodiment of the present invention, and

FIG. 5 shows a schematic block diagram for elucidating an exemplary system concept for realizing the inventive method or for producing the inventively coated extrusion die, respectively.

### DETAILED DESCRIPTION

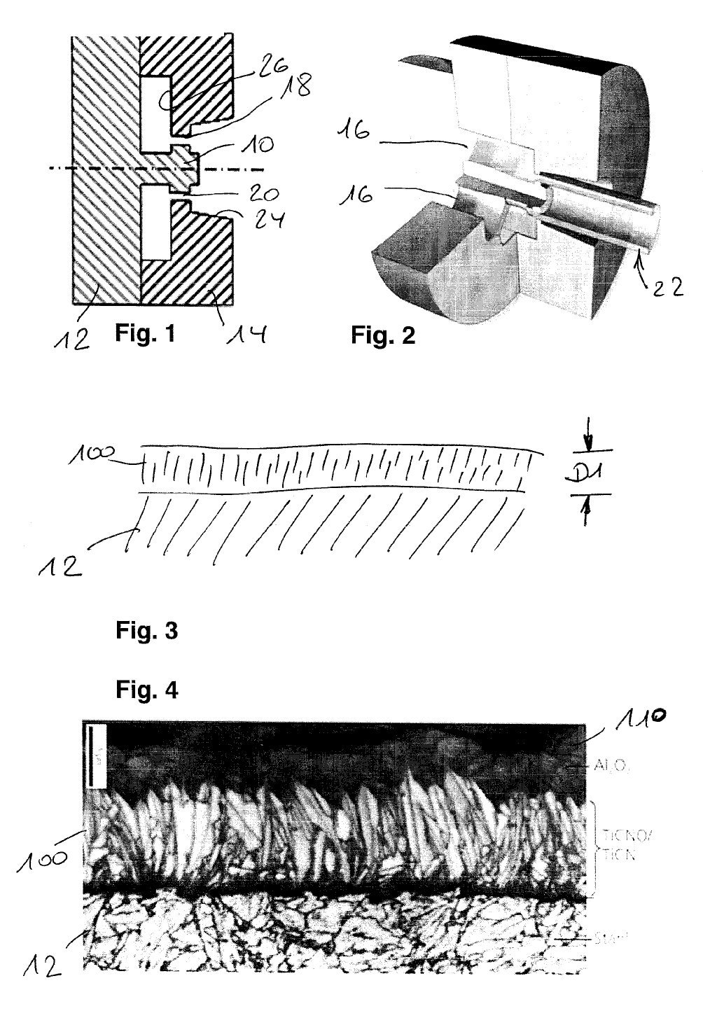

FIGS. 1 and 2 show an otherwise conventionally realized two-part extrusion die. This extrusion die specifically features a mandrel section 12 that forms a mandrel 10, as well as a die bolster 14 that cooperates with the mandrel section. The mandrel section conventionally forms a plurality of inlets 16 around the circumference of the mandrel 10 in order to guide the metal that is ductile during the pressing operation through a pressing channel on the mandrel section 20 formed between the mandrel 10 and a revolving surface 18 of the die bolster 14. The cylinder wall 18 defines the dimensions of this pressing channel, as well as an outside diameter of the obtained tube 22 of, e.g., 30 mm in the example shown (the inside diameter of the obtained tube is defined by a maximum outside diameter of the mandrel 10 and its outside diameter is defined by 18).

The extrusion die shown in FIG. 1 and FIG. 2 is illustrated in a purely exemplary fashion; in the context of the present invention, we also refer, for example, to the exemplary embodiment of EP 1 001 884 B1 with respect to further information on such extrusion dies.

According to the invention, such a die is advantageously provided with a coating on its contact surfaces with the extrusion material as described below. In this case, it is preferred to apply the inventive coating over the entire surface, i.e., all contact surfaces of the die parts are provided with this coating, but the present invention also includes embodiments, in which this coating is only applied selectively or partially, especially on particularly exposed locations, wherein this concerns, in particular, the surfaces that define the pressing channel 20 (namely the outer cylindrical surface 18 of the die bolster and the outer surface area of the mandrel 10), as well as the inner surface 26 of the die bolster situated upstream of the channel 20 and the inner surfaces of the inlets 16. The following description of coating examples elucidates that the present invention, in particular, makes it possible to produce an especially wear-resistant coating that significantly extends the service life of the die shown.

According to the first embodiment of the present invention, the bodies 12 and 14 of the extrusion die shown are made of a high-temperature steel with a corresponding long-term heat resistance (and retention of hardness), typically of an otherwise known hot-work tool steel. Such a Cr—Mo—V alloyed steel is known, for example, in the form of the standardized steel types 2344, 2367 or the like.

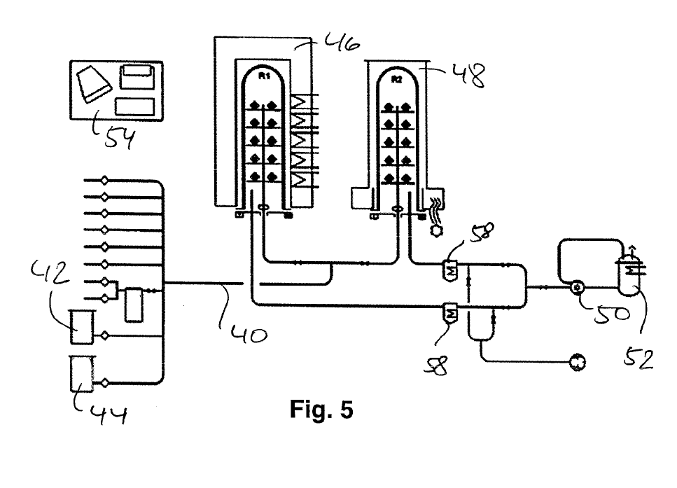

According to the present invention, these steel bodies are now provided with the coating 100 that is schematically illustrated in FIG. 3 during the course of a medium-temperature CVD process. According to the present invention, the process being carried out is a so-called medium-temperature process, i.e. it is carried out in the form of a CVD coating process at a temperature in the range <950° C. and above 700° C., wherein the temperature range between 800° C. and 900° C. proved particularly advantageous for the CVD coating process. A typical realization of a suitable coating system is illustrated in the block diagram according to FIG. 5, in which reaction gases are introduced into a reactor R1, R2 via an arrangement of gas pipes 40; in the present exemplary embodiment, the schematically illustrated gas inflow 42 consists of TiCl₄ and the gas inflow 44 consists of a precursor gas in the form of CH₃CN. An additional supply of hydrogen also takes place. The reactor is heated in otherwise conventional fashion to the temperature required for the deposition of the layer 100, in this case 850° C., by means of a furnace 46, wherein a cooling cover 48 cooled with ambient air subsequently serves for cooling the reactor and the bodies situated in the reactor. A liquid ring pump 50 removes residual gases from the reactor arrangement in cooperation with a neutralization arrangement 52. In the schematic block diagram according to FIG. 5, the structure of which in other respects corresponds to conventional CVD coating systems and is parameterized for the peculiarities of the inventive die coating process, the reference symbol 54 identifies the control unit required for controlling the system; the units identified by the reference symbol 58 represent cooling traps.

In the exemplary embodiment shown, CH3CN and TiCl4 are utilized for carrying out the medium temperature (MT) TiCN coating process.

The reaction temperature amounts to 850° and the participating reaction gases are adapted to the peculiarities of the substrate material of hot-work tool steel in accordance with the invention by being adjusted and parameterized as follows: at a reactor pressure of 50 mbar-200 mbar, the inflow of H2 takes place with approximately 20 l/min, the inflow of TiCl takes place with approximately 3.8 ml/min and the inflow of CH3CN takes place with approximately 0.5 ml/min.

The schematic illustration in FIG. 3 elucidates the result of this exemplary embodiment. A columnar (stalky) layer 10 with a thickness of 5-10 μm is created on the carrier substrate of the die parts 12 and 14. Analogous to the photograph in FIG. 4, the stalky structure indicated in FIG. 3 shows stalks (columns) that are clearly delimited and spaced apart from one another by intermediate spaces, wherein the stalks or columns respectively extend perpendicular to an outer surface of the coating and a substrate surface and, according to the invention, advantageously adhere to the substrate surface such that the toughness of the steel die is increased and advantageous wear properties are realized. At the same time, the thusly coated surface has hardness properties in the range between approximately 2500 HV and 3000 HV.

As a direct result of the above-described stoichiometry of this exemplary process, the coating has a C/N ratio (measured in atomic percent) that corresponds to approximately 1.5:1 (60:40).

A thusly coated die that is also cooled to the ambient temperature after the removal from the CVD reactor and subsequently heat-treated can then be used for extruding typical profiles with common extrusion materials. In the exemplary embodiment illustrated in FIG. 2, the tube 22 has an outside diameter of 30 mm, wherein extrusion material DIN EN 6060 (AlMnSi0.5) is extruded with a production speed of the profile 22 of approximately 20 m/min-30 m/min (referred to the exiting speed of the profile at the die outlet).

In comparison with conventionally coated or uncoated extrusion dies, the profile being produced advantageously has an improved surface quality, particularly a smoother and finer surface (significantly reduced roughness Rₘₐₓ). In contrast to an extrusion die that is coated conventionally (e.g. according to EP 1 011 884 B1), the product temperature at the product outlet is advantageously reduced by approximately 10° C. to 30° C. in the exemplary embodiment being carried out under otherwise identical boundary conditions. This is not only achieved due to the advantageously low coefficients of friction of the inventively coated die, but also an improved heat dissipation into the die bodies 12 and 14 via the stalky coating 100. One advantageous result of this low temperature is a reduced material embrittlement of the die that positively affects the wear resistance. It was furthermore determined in microscopic observations that the coating produced in accordance with the invention respectively features fewer product surface defects such as microscopic bodies (“Pickups”) and results in an improved surface roughness of the profile.

A variation of the present invention that represents a second exemplary embodiment essentially follows the above-described stoichiometry. However, a doping process, e.g. with boron, is additionally carried out during the medium-temperature CVD coating process; boron is introduced into the CVD reaction process in the form of a reaction gas (BCl3).

Such a doping process initially leads to a finer structure of the coating 100, but also causes an increased layer hardness and significantly lowers the so-called adherence tendency of the coating referred to the extrusion metal. In this case, the doping element, e.g. boron, diffuses into the TiCN such that a reduced grain size of the coating is achieved; at the same time, the advantageous columnar structure is preserved.

Another embodiment of the invention is elucidated in the sectional view according to FIG. 4. The scale indicated in the upper left region corresponds to 5 μm.

Analogous to the first exemplary embodiment, a hot-work tool steel was chosen as substrate material for the die bodies 12 and 14 in this exemplary embodiment and a TiCN coating 100 was deposited by means of the above-described stoichiometry. In addition, this coating was doped with Zr, wherein this element was introduced into the CVD reactor in the form of zirconium chlorides. The layer 100 was also produced at a medium temperature in this case, i.e. at a reaction and deposition temperature of 800° C. to 900° C., wherein this medium-temperature layer 100 was in accordance with the scale shown deposited with an effective layer thickness of the stalky structure in the range between approximately 5 μm-10 μm.

In contrast to the exemplary embodiment according to FIG. 3, however, a second layer 110 was applied, in this case by means of Al2O3, subsequent to the medium-temperature process due to the following reaction:

Al+3HCl<->AlCl3+3/2 H2 1.

CO2+H2<->H2O+CO 2.

2AlCl3+3H2O<->Al2O3+6HCl 3.

In contrast to the layer 100, this cover layer (also referred to as functional layer) is deposited at a high temperature, namely at 1000° C. in the exemplary embodiment shown, and has a layer thickness of 2 μm-5 μm after the completion of the process. In contrast to the tough medium-temperature layer 100, the functional layer 110 is particularly hard such that it synergistically interacts with the layer 100 and additionally lowers the abrasion caused by the extrusion process.

According to the invention, however, the subsequent application of the layer 110 advantageously does not change the C/N ratio of the medium-temperature layer 110 such that the overall arrangement illustrated in the form of a sectional view in FIG. 4 maintains its favorable toughness properties realized with the advantageous inventive layer 100, wherein a favorable adhesion of the upper functional layer 110 is also achieved, in particular, due to the columnar or stalky structure.

The thusly produced die also has a Rockwell hardness <60 (typically between 44-55, particularly in the range between 48-54).

The present invention is neither limited to the shown die geometry (or the coated surfaces thereof) nor to the exemplary substrate materials, extrusion materials and coating materials used (including the gases used). In fact, the present invention can be realized with any materials for the layer 100 that are compatible with medium-temperature CVD processes, wherein Ti is preferred as metal element, but does not necessarily have to be present. According to the present invention, it is also possible to dope the thusly produced layer, wherein particularly Zr, Cr or the like may also be considered in addition to the aforementioned element B. Furthermore, the cover layer (functional layer) of Al₂O₃ merely represents an example, wherein it would likewise be possible to apply, e.g., a TiO cover layer or another particularly hard layer that, in contrast to the MT-layer, is applied at a high temperature.

With respect to the die geometry, the present invention is particularly suitable for coating corners and edges that are especially stressed during the extrusion process, wherein it is advantageous, according to enhancements of the invention and in the realization of the invention in the form of an inventively coated extrusion die, to realize the edges in the region of the channel inlet (and/or outlet) with edge geometries that subsequently carry the inventive coating in the range between approximately 0.1 and approximately 2 mm.

In addition to otherwise known and conventional aluminum-based alloys, it is according to the invention also possible, in principle, to utilize other light metals or corresponding alloys such as, e.g., magnesium or zinc alloys or alternatively heavy metal alloys, e.g., on the basis of copper and/or brass (with correspondingly higher processing temperatures) as extrusion material. Independently of the aforementioned metallic extrusion processes, the present invention presumably is also well suited for processing plastics such as, e.g., CFRP plastics or the like in order to improve their wear properties. It can also be expected that particularly hard and abrasive extrusion materials (e.g. powder-metallurgical aluminum with a high Si content that could conceivably reach 14%), as well as aluminum with additives for altering the material characteristics (e.g. nanoparticles, SiC or the like), are processed.

In contrast to conventional high-temperature coating technology, the present invention therefore makes it possible to provide a medium-temperature layer on a (hot-work tool) steel substrate in the form of an extrusion die in a surprisingly simple and effective fashion, wherein this coating is either realized in the form of a single-layer coating or alternatively in the form of a multilayer coating, for example, with another layer in the form of a high-temperature functional layer applied thereon.

1. A method for producing a single-layer or multilayer coating on a substrate body in the form of an extrusion die of a high-temperature and/or long-term heat-resistant steel material by means of chemical vapor deposition (CVD), comprising the steps of:
(a) providing the substrate body of the steel material having a long-term heat resistance at an extrusion temperature in the range between 400° C. and 950° C. and is intended for interacting with ductile extrusion metal;
(b) introducing a first reaction gas containing a metal into a reactor accommodating the substrate body in order to provide a coating metal;
(c) introducing a second reaction gas containing a carbon compound into the reactor in order to provide carbon for the coating;
(d) at least one of the first and the second reaction gas or an additional reaction gas, provides nitrogen for the coating;
(e) carrying out a CVD coating process with the reaction gases at a medium temperature in the range of 700° C. to 950° C. in order to produce the coating such that the weight ratio and/or atomic percent ratio, between carbon and nitrogen in the at least one layer of the coating amounts to C/N>1 and/or the at least one layer of the coating has a columnar and/or stalky structure with a plurality of column-like microstructure sections that are arranged adjacent to one another and aligned parallel to one another and perpendicular to the substrate surface.

2. The method according to claim 1, wherein the first reaction gas for the coating metal of the metal compound comprises a metal is selected from the group consisting of: Ti, Zr, B, Cr, Cu, Mg, Hf and mixtures thereof.

3. The method according to claim 1, wherein the first reaction gas contains TiCl₄.

4. The method according to claim 2, wherein the second reaction gas is selected from the group consisting of CH₃CN, C₂H₆ and mixtures thereof.

5. The method according to claim 1, wherein the long-term heat-resistant steel has after the coating process is characterized by a toughness determined with a method for determining the impact work according to DIN SEP 1314 in the range between 200 J and 400 J and a hardness in the range between 44 HRC and 55 HRC.

6. The method according to claim 1, wherein the at least one layer of the coating is deposited with a layer thickness of 5 μm-15 μm.

7. The method according to claim 6, wherein a cover layer is applied onto the coating above a medium CVD temperature of 950° C.

8. The method according to claim 7, wherein the material of the cover layer is selected from the group consisting of TiO, Al2O3, TiBN and mixtures thereof.

9. The method according to claim 7, wherein the cover layer or an outer layer of the coating has a surface roughness in a range between Rz 0μ-4μ and a hardness measured according to Vickers in the range between 2000 and 3500 HV.

10. The method according to claim 1, wherein the coated substrate body is heat-treated with a tempering temperature or artificial aging temperature after the completion of the CVD coating process.

11. The method according to claim 1, wherein an extrusion die is realized in the form of a two-part die (10, 12) with a mandrel part and a die bolster, and the coating respectively is produced on the mandrel part and on the die bolster.

12. The method according to claim 11, wherein the coating is applied onto the walls of the die that define a guide channel and/or a flow channel for the ductile extrusion material, wherein an inlet edge and/or outlet edge of the channel has a radius that is provided with the coating.

13. The method according to claim 1, wherein the long-term heat-resistant steel has after the coating process is characterized by a toughness determined with a method for determining the impact work according to DIN SEP 1314 in the range between 250 J and 350 J and a hardness in the range between 48 HRC and 54 HRC.

14. The method according to claim 1, wherein the at least one layer of the coating is deposited with a layer thickness between 7 μm-11 μm.

15. The method according to claim 7, wherein the cover layer or an outer layer of the coating has a surface roughness in a range between Rz 1μ-2.5μ and a hardness measured according to Vickers in the range between 2500 and 3000 HV.

16. The method according to claim 1, wherein the substrate body of the steel material has a long-term heat resistance at an extrusion temperature in the range between 500° C. and 640° C. and is intended for interacting with ductile extrusion metal.

17. The method according to claim 1, wherein a first reaction gas containing titanium is introduced into a reactor accommodating the substrate body in order to provide a coating metal.

18. The method according to claim 1, wherein a CVD coating process is carried out with the reaction gases at a medium temperature in the range of 800° C. to 900° C., in order to produce the coating such that the weight ratio and/or atomic percent ratio, between carbon and nitrogen in the at least one layer of the coating amounts of C/N>=1.5, preferably to C/N>2.
